(19) United States
(12) Patent Application Publication
(10) Pub. No.: US 2024/0227113 A1
(43) Pub. Date: Jul. 11, 2024

(54) POLISHING PAD AND METHOD OF MONITORING A POLISHING PROCESS USING THE SAME

(71) Applicant: SK enpulse Co., Ltd., Gyeonggi-do (KR)

(72) Inventors: Joonho AN, Gyeonggi-do (KR); Jangwon SEO, Gyeonggi-do (KR); Chang Gyu IM, Gyeonggi-do (KR); Kyung Hwan KIM, Gyeonggi-do (KR); Yujin SHIN, Gyeonggi-do (KR)

(21) Appl. No.: 18/538,695

(22) Filed: Dec. 13, 2023

(30) Foreign Application Priority Data
Jan. 6, 2023 (KR) 10-2023-0002342

(51) Int. Cl. B24B 37/013; B24B 37/22

(52) U.S. Cl. CPC B24B 37/013; B24B 37/22

(57) ABSTRACT

The embodiment relates to a polishing pad that comprises a top pad layer. The top pad layer comprises a light transmitting region for monitoring a change in the state of the polishing pad. The embodiment can efficiently monitor a change in the state of the polishing pad while the polishing process is carried out.

### CROSS-REFERENCE OF RELATED APPLICATIONS

This application claims priority under 35 U.S.C. § 119 to Korean Patent Application No. 10-2023-0002342 filed on Jan. 6, 2023, which is incorporated herein by reference in its entirety.

### TECHNICAL FIELD

Embodiments relate to a method for monitoring the state of a polishing pad used in a chemical mechanical polishing (CMP) process and/or the state of a wafer that is subjected to polishing in the CMP process, and to a polishing pad therefor.

### BACKGROUND ART

A polishing pad serves to remove unnecessary portions present on a wafer and makes the surface of the wafer smooth in a chemical mechanical polishing (CMP) process.

Since a polishing pad directly affects the reliability of a CMP process, it is necessary to maintain its condition stably. Specifically, as a polishing pad wears out repeatedly in a CMP process, its condition, such as the thickness and surface roughness of the polishing pad, changes. Such changes need to be detected (observed) at an appropriate time to condition the polishing pad or replace the polishing pad to obtain a highly reliable wafer.

In order to check a change in the state of a polishing pad, a technology for detecting a change in the thickness of the polishing pad using an eddy current sensor or an optical distance measuring sensor has been proposed. However, it is difficult to accurately determine, with this technology, how much wear has actually occurred on the polishing pad and how much the thickness of the polishing pad has changed. There is also a limitation in the accuracy of measuring changes in the state of each part of the polishing pad.

Accordingly, there is a need for a technology that can accurately and reliably check a change in the state of a polishing pad.

### PRIOR ART DOCUMENT

### Patent Document

(Patent Document 1) Korean Patent No. 2013-0018604

### DETAILED DESCRIPTION OF THE INVENTION

### Technical Problem

An embodiment aims to provide a polishing pad that can efficiently check a change in the state, such as thickness and surface roughness, when a CMP process is carried out repeatedly.

In addition, an embodiment aims to provide a method for monitoring a polishing process that can monitor a change in the state of a polishing pad and/or the state of a wafer in a CMP process.

### Solution to the Problem

According to an embodiment to solve the above problem, there is provided a polishing pad, which comprises a top pad layer, wherein the top pad layer comprises a light transmitting region for monitoring a change in the state of the polishing pad.

In addition, according to another embodiment, there is provided a method for monitoring a polishing process, which comprises (1) placing a wafer on a polishing pad comprising a top pad layer comprising a light transmitting region to carry out a polishing process; (2) scanning light to the light transmitting region from a first optical displacement detection sensor located above the light transmitting region; and (3) detecting light reflected from the light transmitting region by the first optical displacement detection sensor to monitor a change in the state of the polishing pad.

### Advantageous Effects of the Invention

The polishing pad according to the embodiment comprises a light transmitting region capable of accurately monitoring a change in the state of the polishing pad in real time. Thus, it is possible to determine relatively accurately when the polishing pad needs to be conditioned or replaced during the repeated CMP process. Accordingly, the embodiment can ensure that the polishing pad is maintained in an optimal state during the CMP process, thereby providing a wafer with high reliability.

In addition, since the polishing pad according to the embodiment further comprises a window region for detecting the termination point of polishing a wafer, it is possible to determine the termination point of polishing a wafer. Accordingly, the embodiment may exhibit overall enhanced efficiency of the polishing process.

### BRIEF DESCRIPTION OF THE DRAWINGS

FIG. 1 is a cross-sectional view showing a polishing pad according to an embodiment.

FIG. 2 is a cross-sectional view showing a polishing pad according to another embodiment.

FIG. 3 is a plan view showing the surface shape and arrangement structure of a light transmitting region according to an embodiment.

FIG. 4 is a reference diagram for illustrating a method for monitoring a polishing process according to an embodiment.

FIG. 5 is a reference diagram for illustrating a method for monitoring a polishing process according to another embodiment.

FIG. 6 is a graph showing the evaluation results according to Test Example 1.

FIG. 7 is a graph showing the evaluation results according to Test Example 2.

### REFERENCE NUMERAL OF THE DRAWINGS

100: polishing pad
10: top pad layer
11: light transmitting region
12: polishing region
11a: light transmitting polymer region
11b: light reflector
20: adhesive layer
30: sub pad layer
40: window region
50: partition wall
S₁: first optical displacement detection sensor
S_{A}: first optical scanning unit
S_{B}: first light detection unit
S₂: second optical displacement detection sensor
S_{C}: second optical scanning unit
S_{D}: second light detection unit
W: wafer

### BEST MODE FOR CARRYING OUT THE INVENTION

Hereinafter, the present invention will be described with reference to embodiments. Here, the embodiments are not limited to what has been disclosed below. The embodiments may be modified into various forms as long as the gist of the invention is not altered.

In the present specification, in the case where an element is mentioned to be formed, connected, or combined on or under another element, it means all of the cases where one element is directly, or indirectly through another element, formed, connected, or combined with another element. In addition, it should be understood that the criterion for the terms on and under of each component may vary depending on the direction in which the object is observed.

In the present specification, the term “comprising” is intended to specify a particular characteristic, region, step, process, element, and/or component. It does not exclude the presence or addition of any other characteristic, region, step, process, element and/or component, unless specifically stated to the contrary.

All numbers and expressions related to the quantities of components, reaction conditions, and the like used herein are to be understood as being modified by the term “about,” unless otherwise indicated.

The terms first, second, and the like are used herein to describe various elements, and the elements should not be limited by the terms. The terms are used for the purpose of distinguishing one element from another.

For the sake of description, the sizes of individual elements in the appended drawings may be exaggeratedly depicted, and they may differ from the actual sizes.

The embodiment is characterized by adopting a light transmitting region separate from a conventional window region in a polishing pad, thereby enabling accurate real-time monitoring of a change in the state of the polishing pad in a CMP process. Hereinafter, this will be described in detail.

### Polishing Pad

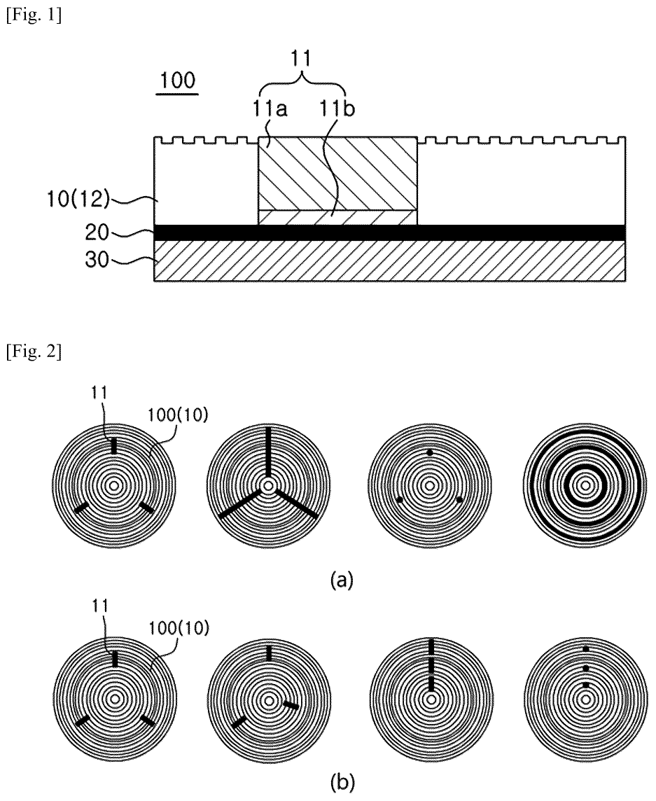

The polishing pad according to an embodiment comprises a top pad layer and may optionally further comprise an adhesive layer, a sub pad layer, a window region, and a partition wall. This will be described in detail with reference to FIGS. 1 to 3.

### Top Pad Layer

The top pad layer (10) adopted in the polishing pad (100) according to an embodiment serves to polish a wafer that is subjected to polishing. The top pad layer (10) may be formed (prepared) using composition A (a composition for forming a top pad) comprising a urethane-based prepolymer, a curing agent, and a foaming agent.

The urethane-based prepolymer contained in composition A may be a polymer prepared by reacting a polyol compound and an isocyanate compound. The urethane-based prepolymer may have a weight average molecular weight (Mw) of 500 to 3,000 g/mole, specifically, 600 to 2,000 g/mole, 700 to 1,500 g/mole, or 800 to 1,000 g/mole. In addition, the urethane-based prepolymer may have an isocyanate group content (the weight of isocyanate groups (—NCO) present as a free reactive group without reacting with urethane in percentage, NCO %) of 6 to 10% by weight, specifically, 7 to 9% by weight or 7.5% by weight to 8.5% by weight. As the weight average molecular weight and the isocyanate group content of the urethane-based prepolymer are within the above ranges, the top pad layer (10) with high mechanical properties may be formed.

The polyol compound for preparing the urethane-based prepolymer may be at least one polyol selected from the group consisting of a polyether polyol, a polyester polyol, a polycarbonate polyol, and an acryl polyol. More specifically, the polyol compound may comprise at least one selected from the group consisting of polytetramethylene ether glycol, polypropylene ether glycol, ethylene glycol, 1,2-propylene glycol, 1,3-propylene glycol, 1,2-butanediol, 1,3-butanediol, 2-methyl-1,3-propanediol, 1,4-butanediol, neopentyl glycol, 1,5-pentanediol, 3-methyl-1,5-pentanediol, 1,6-hexanediol, diethylene glycol, dipropylene glycol, and tripropylene glycol.

The polyol compound may comprise a low molecular weight polyol having a weight average molecular weight (Mw) of 100 to less than 300 g/mole and a high molecular weight polyol having a weight average molecular weight (Mw) of 300 to 1,800 g/mole. As the polyol compound is a mixture of the low molecular weight polyol and the high molecular weight polyol, the top pad layer (10) having high mechanical properties and an appropriate pore size may be formed.

The isocyanate compound for preparing the urethane-based prepolymer may specifically be at least one selected from the group consisting of an aromatic diisocyanate, an aliphatic diisocyanate, and an alicyclic diisocyanate. More specifically, the isocyanate compound may comprise at least one selected from the group consisting of 2,4-toluene diisocyanate, 2,6-toluene diisocyanate, naphthalene-1,5-diisocyanate, p-phenylene diisocyanate, tolidine diisocyanate, 4,4′-diphenylmethane diisocyanate, hexamethylene diisocyanate, dicyclohexylmethane diisocyanate, and isophorone diisocyanate.

The curing agent contained in composition A may comprise a compound that undergoes a curing reaction with the urethane-based prepolymer. Specifically, the curing agent may comprise at least one selected from the group consisting of an aromatic amine, an aliphatic amine, an aromatic alcohol, and an aliphatic alcohol. More specifically, the curing agent may comprise at least one selected from the group consisting of 4,4′-methylenebis(2-chloroaniline), diethyltoluenediamine, diaminodiphenylmethane, dimethyl thio-toluene diamine, propanediol bis-p-aminobenzoate, diaminodiphenyl sulphone, m-xylylenediamine, isophoronediamine, ethylenediamine, diethylenetriamine, triethylenetetramine, polypropylenediamine, polypropylenetriamine, and bis(4-amino-3-chlorophenyl)methane.

The content of the curing agent may be 18 to 28 parts by weight, specifically 19 to 27 parts by weight or 20 to 26 parts by weight, relative to 100 parts by weight of the urethane-based prepolymer.

The foaming agent contained in composition A may specifically comprise at least one selected from the group consisting of a solid phase foaming agent, a gas phase foaming agent, and a liquid phase foaming agent. More specifically, the foaming agent may be a solid phase foaming agent, a gas phase foaming agent, or a mixture thereof.

The solid phase foaming agent may be a foaming agent that comprises expandable particles. The expandable particles are particles having a characteristic that can be expanded by heat or pressure. The final size may be determined by heat or pressure applied in the process of preparing the top pad layer (10). Specifically, the expandable particles may be thermally expanded particles, unexpanded particles, or a combination thereof. The thermally expanded particles are particles previously expanded by heat. They refer to particles having little or no change in size by heat or pressure applied during the process of preparing the top pad layer (10). The unexpanded particles are particles that have not been previously expanded by heat. They refer to particles whose final size is determined when expanded by heat or pressure applied during the process of preparing the top pad layer (10).

The expandable particles may comprise a shell of a resin; and an expansion-inducing component encapsulated inside the shell.

The shell may comprise a thermoplastic resin. Here, the thermoplastic resin may comprise at least one selected from the group consisting of a vinylidene chloride-based copolymer, an acrylonitrile-based copolymer, a methacrylonitrile-based copolymer, and an acrylic-based copolymer.

The expansion-inducing component may comprise at least one selected from the group consisting of a hydrocarbon compound, a chlorofluoro compound, and a tetraalkylsilane compound.

Specifically, the hydrocarbon compound may comprise at least one selected from the group consisting of ethane, ethylene, propane, propene, n-butane, isobutane, n-butene, isobutene, n-pentane, isopentane, neopentane, n-hexane, heptane, and petroleum ether.

The chlorofluoro compound may comprise at least one selected from the group consisting of trichlorofluoromethane (CCl₃F), dichlorodifluoromethane (CCl₂F₂), chlorotrifluoromethane (CClF₃), and dichlorotetrafluoroethylene (CClF₂—CClF₂).

The tetraalkylsilane compound may comprise at least one selected from the group consisting of tetramethylsilane, trimethylethylsilane, trimethylisopropylsilane, and trimethyl-n-propylsilane.

The content of the solid phase foaming agent may be 0.5 to 10 parts by weight, specifically, 1 to 5 parts by weight, 1.3 to 3 parts by weight, or 1.3 to 2.6 parts by weight, relative to 100 parts by weight of the urethane-based prepolymer.

The gas phase foaming agent may be a foaming agent comprising a commonly known inert gas (e.g., nitrogen gas (N₂), argon gas (Ar), helium gas (He), or the like).

The gas phase foaming agent may be fed through a predetermined feeding line while the urethane-based prepolymer, the curing agent, and/or the solid phase foaming agent are mixed. The feeding rate of the gas phase foaming agent may be 0.8 to 2.0 L/minute, 0.7 to 1.8 L/minute, or 1.0 to 1.7 L/minute.

Composition A may further comprise at least one additive selected from the group consisting of surfactants (e.g., silicone-based surfactants), pH regulating agents, antioxidants, reaction rate regulating agents, thermal stabilizers, and dispersion stabilizers.

The top pad layer (10) formed from composition A comprises a light transmitting region (11) for monitoring a change in the state of the polishing pad (100). Specifically, the top pad layer (10) may comprise a polishing region (12) for polishing a wafer and a light transmitting region (11) for checking a change in the state of the polishing pad (100) in real time. The polishing region (12) may comprise a cured product of composition A (a composition for forming a top pad) described above. The light transmitting region (11) refers to a medium region through which externally irradiated light enters and penetrates and may comprise a light transmitting substance.

According to an embodiment, the light transmitting region (11) may have physical properties (mechanical properties) at the same level as those of the top pad layer (10) (specifically, the polishing region (12) of the top pad layer (10)). That is, the physical properties of the light transmitting region (11) may be the same as those of the top pad layer (10). Here, the physical properties include hardness, strength (tensile strength, yield strength), elongation, stretching ratio, and Young's modulus. For example, the light transmitting region (11) may have at least one physical property selected from the group consisting of hardness, strength, elongation, stretching ratio, and Young's modulus at the same level (the same) as at least one physical property of the top pad layer selected from the group consisting of hardness, strength, elongation, stretching ratio, and Young's modulus (10) (specifically, the polishing region (12) of the top pad layer (10)). As the physical properties of the light transmitting region (11) are the same as those of the top pad layer (10), a change in the state of the polishing pad (100) can be monitored in real time, and, at the same time, the efficiency of the polishing process can be increased. That is, as the physical properties are the same, the light transmitting region (11) is also worn during the polishing process in the same way as the top pad layer (10). As the state of the light transmitting region (11) that has been worn is monitored, a change in the state of the top pad layer (10) can be accurately checked in real time. In addition, the light transmitting region (11), along with the top pad layer (10), also plays a role in polishing the polishing target, thereby increasing the efficiency of the polishing process.

According to an embodiment, the light transmitting region (11) may comprise a light transmitting polymer region (11a) and a light reflector (11b), whereby a change in the state of the polishing pad (100) can be checked more accurately and specifically.

The light transmitting polymer region (11a) which polishes the wafer while monitoring the state changes of the polishing pad (100) may have physical properties at the same level of the top pad layer (10)(specifically, the polishing region (12) of the top pad layer (10)). This light transmitting polymer region (11a) may be formed (prepared) using composition B (a composition for forming a light transmitting polymer region) for forming the light transmitting polymer region (11a).

The light transmitting polymer formed in the light transmitting polymer region (11a) from composition B may be a commonly known light transmitting photocuring polymer, a light transmitting thermosetting polymer, or a combination thereof. Specifically, the light transmitting polymer may comprise at least one selected from the group consisting of polycarbonate (PC), polyethylene terephthalate (PET), polyether sulfone (PES), polyvinyl alcohol (PVA), polymethyl methacrylate (PMMA), polyethylene terephthalate glycol (PETG), triacetylcellulose (TAC), cycloolefin polymers (COPs), cycloolefin copolymers (COCs), acrylic resins, and urethane resins.

The urethane resin may be a resin formed from a composition that comprises a urethane-based prepolymer and a curing agent. Specifically, composition B may be a composition comprising the urethane-based prepolymer and curing agent described in the section of the top pad layer (10) while it does not comprise a foaming agent. As the light transmitting polymer region (11a) is formed from such composition B, there may be no voids (pores). Since the description on the urethane-based prepolymer and curing agent contained in composition B (a composition for forming a light transmitting polymer region) is the same as the description on the urethane-based prepolymer and curing agent given in the section of the top pad layer (10), the detailed description thereon is omitted.

Composition B may further comprise at least one additive selected from the group consisting of curing agents, curing accelerators, dispersants, viscosity modifiers, antifoaming agents, leveling agents, chain extenders, surfactants (e.g., silicone-based surfactants), pH regulating agents, antioxidants, reaction rate regulating agents, thermal stabilizers, and dispersion stabilizers.

The light reflector (11b) is provided below the light transmitting polymer region (11a) and serves to reflect light incident on the light transmitting polymer region (11a) to the outside. This light reflector (11b) may comprise a commonly known light reflection material. Specifically, the light reflector (11b) may comprise at least one metal-based material selected from the group consisting of aluminum (Al), silver (Ag), nickel (Ni), tungsten (W), titanium (Ti), platinum (Pt), gold (Au), palladium (Pd), chromium (Cr), titanium (Ti), and stainless steel (SUS).

The thickness of the light reflector (11b) is not particularly limited, but it may specifically be 0.05 to 1 mm, 0.07 to 0.5 mm, 0.1 to 0.3 mm, or 0.1 to 0.15 mm. As the thickness of the light reflector (11b) is within the above range, the overall physical properties and manufacturing cost of the polishing pad can be optimized while it smoothly performs the role of light reflection.

The surface roughness of the light transmitting region (11) (specifically the light transmitting polymer region (11a)) comprising the light transmitting polymer region (11a) and the light reflector (11b) may be at the same level as the surface roughness of the top pad layer (10), specifically may be the same. That is, a plurality of grooves are formed on the surface of the top pad layer (10) to ensure the fluidity of a polishing slurry used in the polishing process and to increase the efficiency of wafer planarization. A plurality of grooves similar to the grooves formed on the surface of the top pad layer (10) may be formed on the surface of the light transmitting region (11). As a result, the light transmitting region (11) and the top pad layer (10) may have the same surface roughness. As the surface roughness of the light transmitting region (11) and that of the top pad layer (10) are the same, the light transmitting region (11) also plays a role in securing the fluidity of a polishing slurry like the top pad layer (10), whereby the efficiency of the polishing process can be increased.

According to an embodiment, a change in the state of the polishing pad (100) can be checked by monitoring a change in the thickness or surface roughness of the light transmitting region (11) (specifically, the light transmitting polymer region (11a)). That is, when the polishing process is carried out, the top pad layer (10) and the light transmitting region (11) contained therein are worn together, resulting in a change in the thickness of the light transmitting region (11) or a change in the surface roughness thereof. An embodiment is to monitor a change in the thickness, or a change in the surface roughness, of the polishing pad (100) (specifically, the top pad layer (10)) through the change in the thickness, or the change in the surface roughness, of the light transmitting region (11). As the change in the thickness, or surface roughness, of the light transmitting region (11) that is directly caused by wear as described above is checked, a change in the state of the polishing pad (100) can be checked more accurately and specifically.

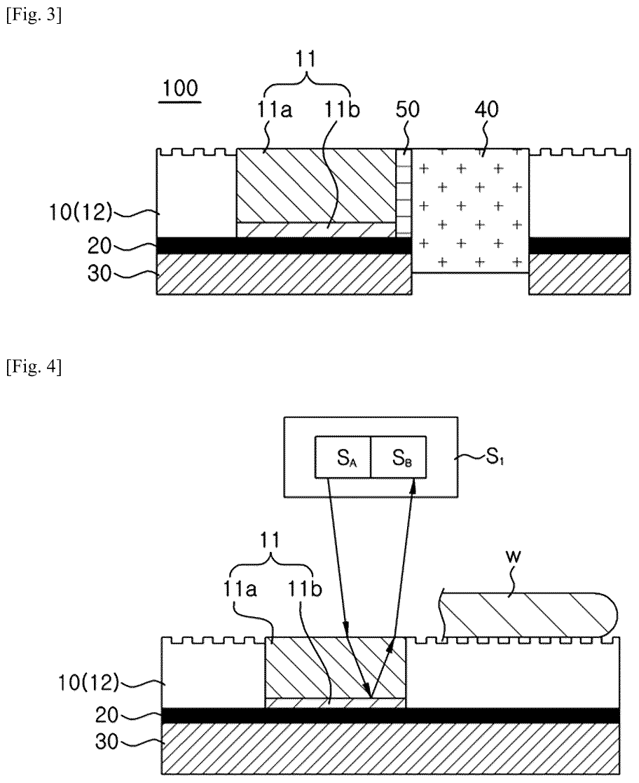

According to an embodiment, the surface shape of the light transmitting region (11) is not particularly limited. Specifically, it may have at least one surface shape selected from the group consisting of polygons (e.g., squares, pentagons, hexagons, or the like), circles, rings, and spirals (see FIG. 2 (a)). More specifically, the surface shape of the light transmitting region (11) may preferably be spiral so that a change in the state of the polishing pad (100) can be checked uniformly without deviation.

In addition, the arrangement structure of the light transmitting region (11) is not particularly limited. Specifically, it may have at least one surface shape selected from the group consisting of radial, uniformly arranged, non-uniformly arranged, and straight types (see FIG. 2 (b)).

The thickness of the top pad layer (10) comprising the light transmitting region (11) is not particularly limited. Specifically, it may be 1 to 5 mm, 1 to 4 mm, 1 to 3.5 mm, or 1 to 3 mm. As the thickness of the top pad layer (10) is within the above range, the polishing process can be carried out stably, and the polishing pad (100) can be made lighter.

### Adhesive Layer

The adhesive layer (20), which is optionally further adopted in the polishing pad (100) according to an embodiment, serves to bond the top pad layer (10) and a sub pad layer (30). Further, the adhesive layer (20) may also serve to prevent a polishing slurry supplied to the top pad layer (10) from leaking into the sub pad layer (30). The adhesive layer (20) may be formed (prepared) using a hot melt adhesive composition.

The hot melt adhesive composition may comprise a commonly known hot melt adhesive. The hot melt adhesive may specifically comprise at least one selected from the group consisting of a polyurethane resin, a polyester resin, an ethylene-vinyl acetate resin, a polyamide resin, and a polyolefin resin. The hot melt adhesive may have a melting point of 90 to 130° ° C., 100 to 130° ° C., or 110 to 130° ° C.

The thickness of the adhesive layer (20) is not particularly limited, but it may specifically be 5 to 30 μm, 10 to 30 μm, 20 to 27 μm, or 23 to 25 μm. As the thickness of the adhesive layer (20) is within the above range, the polishing pad (100) may be made lighter while the bonding force (adhesive strength) between the top pad layer (10) and the sub pad layer (30) is secured.

### Sub Pad Layer

The sub pad layer (30), which is optionally further adopted in the polishing pad (100) according to an embodiment, is provided below the top pad layer (10). It serves to stably support the top pad layer (10) and to absorb and/or disperse an impact applied to the top pad layer (10). The sub pad layer (30) may be formed (prepared) using a nonwoven fabric or a porous pad.

The hardness of the sub pad layer (30) may be less than the hardness of the top pad layer (10). In addition, the porosity of the sub pad layer (30) may be greater than the porosity of the top pad layer (10).

The thickness of the sub pad layer (30) is not particularly limited. Specifically, it may be 0.5 to 5 mm, 1 to 4 mm, 2 to 3.5 mm, or 1.5 to 3 mm. As the thickness of the sub pad layer (30) is within the above range, it can stably support the top pad layer (10), and the polishing pad (100) can be made lighter.

### Window Region

The window region (40), which is optionally further adopted in the polishing pad (100) according to an embodiment, is distinguished from the light transmitting region (11). It serves to detect the polishing termination point of the wafer that is subjected to polishing. Specifically, the window region (40) is provided adjacent to the light transmitting region (11). It can measure the flatness and thickness of the wafer surface in real time through the window region (40) and determine the polishing termination point of the wafer according to the measurement results. The window region (40) may be formed (prepared) using composition C (a composition for forming a window region) comprising a urethane-based prepolymer and a curing agent, without a foaming agent. Thus, there may be no voids (pores) in the window region (40).

Since the description on the urethane-based prepolymer and curing agent contained in composition C is the same as the description on the urethane-based prepolymer and curing agent given in the section of the top pad layer (10), the detailed description thereon is omitted. In addition, composition C may further comprise the additives described in the section of the top pad layer (10).

The window region (40) may have a light transmittance of 50 to 85%, 55 to 80%, or 60 to 80%. In addition, the window region (40) may have a refractive index of 1.40 to 1.65, 1.45 to 1.60, or 1.48 to 1.58. As the light transmittance and the refractive index are within the above ranges, the polishing termination point of a wafer can be detected more accurately.

The thickness of the window region (40) is not particularly limited. Specifically, it may be 1 to 5 mm, 1 to 4 mm, 1 to 3.5 mm, or 1 to 3 mm. As the thickness of the window region (40) is within the above range, the polishing process can be carried out stably while the accuracy of detecting the polishing termination point is increased.

### Partition Wall

The partition wall (50), which is optionally further adopted in the polishing pad (100) according to an embodiment, is provided between the light transmitting region (11) and the window region (40). It serves to prevent light scattering. Specifically, the partition wall (50) serves to prevent light irradiated from the outside from being scattered in the procedure of passing through the window region (40) to reach the wafer surface, thereby increasing the accuracy of detecting the polishing termination point of a wafer. This partition wall (50) may comprise a commonly known light non-transmitting material. Specifically, the partition wall (50) may comprise at least one material selected from the group consisting of a polyether polyol, a polyester polyol, a polycarbonate polyol, and an acryl polyol.

The size, shape, and structure of the partition wall (50) may not be particularly limited as long as the size, shape, and structure thereof can prevent light scattering.

The polishing pad according to an embodiment comprises a light transmitting region capable of accurately monitoring the state of the polishing pad in real time as described above. Thus, it is possible to determine the optimal timing for conditioning or replacing the polishing pad when a polishing process is carried out using the same. In addition, the polishing pad according to an embodiment may have a composite structure of a light transmitting region and a window region. Thus, it is possible to determine the timing for conditioning or replacing a polishing pad, as well as the polishing termination point of a wafer, resulting in enhanced efficiency of a polishing process.

### Method for Monitoring a Polishing Process

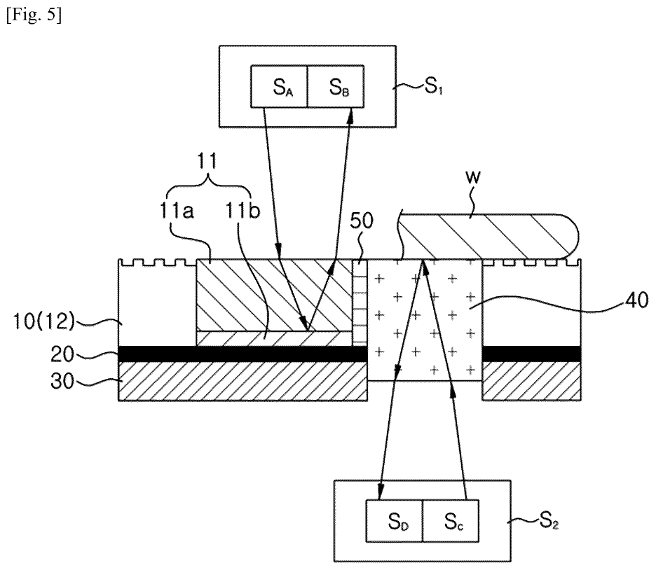

An embodiment provides a method for monitoring a polishing process using the polishing pad described above. Specifically, the method for monitoring a polishing process according to an embodiment comprises (1) placing a wafer on a polishing pad comprising a top pad layer comprising a light transmitting region to carry out a polishing process; (2) scanning light to the light transmitting region from a first optical displacement detection sensor located above the light transmitting region; and (3) detecting light reflected from the light transmitting region by the first optical displacement detection sensor to monitor a change in the state of the polishing pad. Hereinafter, this will be described by referring to FIGS. 4 and 5.

### Step (1) Conducting a Polishing Process

Step (1) according to an embodiment is to place a wafer (W) on a polishing pad comprising a top pad layer (10) to carry out a polishing process. Here, the top pad layer (10) comprises a light transmitting region (11) to monitor a change in the state of the polishing pad (specifically, the top pad layer (10)) during a polishing process. The polishing process may be carried out at a predetermined polishing speed (or polishing time) while the polishing pad is fixed to the platen, and a commonly known polishing slurry is supplied onto the top pad layer (10).

Here, since the polishing pad according to an embodiment monitors a change in the state of the polishing pad through the light transmitting polymer region (11a) provided in the top pad layer (10) and the light reflector (11b) provided below it, the polishing process can be carried out using a prototype without the need to separately modify the polishing device including the platen. That is, conventionally, a light irradiation means (sensor) is provided at the bottom of the platen, and modification work such as forming a hole in the platen had to be performed to monitor the condition of a polishing pad. The embodiment can accurately and specifically monitor the polishing pad even without performing such modification work (the first optical displacement detection sensor (S₁) is located above the polishing pad).

### Step (2): Optical Scanning by the First Optical Displacement Detection Sensor

Step (2) according to an embodiment is to scan light to the light transmitting region (11) from a first optical displacement detection sensor (S₁) located above the light transmitting region (11). Specifically, the first optical scanning unit (S_{A}) contained in the first optical displacement detection sensor (S₁) scans light toward the light transmitting region (11) during the polishing process. Here, the scanned light passes through the light transmitting polymer region (11a) contained in the light transmitting region (11) to reach the light reflector (11b) (see FIGS. 4 and 5).

The first optical displacement detection sensor (S₁) may be a commonly known sensor capable of detecting optical displacement (e.g., phase difference, speed difference, or the like) while scanning light. This first optical displacement detection sensor (S₁) performs repetitive operation (detection). Here, as it is set to operate in view of the shape and arrangement structure of the light transmitting region (11), overload can be prevented.

### Step (3): Monitoring a Change in the State of the Polishing Pad

Step (3) according to an embodiment is to detect light reflected from the light transmitting region (11) by the first optical displacement detection sensor (S₁) to monitor a change in the state of the polishing pad. Specifically, the light that reaches the light reflector (11b) in step (2) is reflected by the light reflector (11b), passes through the light transmitting polymer region (11a) again, and comes out to be incident on the first light detection unit (S_{B}) contained in the first optical displacement detection sensor (S₁). The first light detection unit (S_{B}) detects incident light (reflected light) to determine whether the state of the polishing pad has changed.

A change in the state of the polishing pad may be checked by monitoring a change in the thickness or surface roughness of the light transmitting region (11) (specifically, the light transmitting polymer region (11a)) by the first light detection unit (S_{B}). That is, the light transmitting region (11), along with the polishing pad, is also worn during the polishing process, thereby causing a change in the thickness or surface roughness, which is detected by the first light detection unit (S_{B}) in the first optical displacement detection sensor (S₁). When the thickness or surface roughness of the light transmitting region (11) changes, monitoring is performed through a procedure of determining that the thickness or surface roughness of the polishing pad has also changed.

Specifically, according to an embodiment, the first light detection unit (S_{B}) in the first optical displacement detection sensor (S₁) detects a phase change, a speed change, or an intensity change of reflected light (light incident on the first light detection unit (S_{B})) due to a change in the thickness or surface roughness of the light transmitting region (11) to monitor a change in the thickness, or a change in surface roughness, of the polishing pad.

### Step (4): Detection of Polishing Termination Point

Meanwhile, the method for monitoring a polishing process according to an embodiment may further comprise (4) detecting the polishing termination point of the wafer (W) through the window region (40) further adopted in the polishing pad.

Specifically, according to an embodiment, step (4) may comprise (4-1) scanning light toward the window region (40) from a second optical displacement detection sensor (S₂) located below the window region; and (4-2) detecting light reflected from the window region (40) by the second optical displacement detection sensor (S₂) to determine the polishing termination point of the wafer (W).

Step (4-1) according to an embodiment is to scan light toward the window region (40) from a second optical scanning unit (S_{C}) contained in the second optical displacement detection sensor (S₂) located below the window region. Here, the scanned light passes through the window region (40) to reach the wafer (W) (see FIG. 5).

Step (4-2) according to an embodiment is to detect light reflected from the window region (40) by the second optical displacement detection sensor (S₂) to determine the polishing termination point of the wafer (W). Specifically, the light that reaches the wafer (W) in step (4-1) is reflected, passes through the window region (40) again, and comes out to be incident on the second light detection unit (S_{D}) contained in the second optical displacement detection sensor (S₂). The second light detection unit (S_{D}) detects incident light (reflected light) to determine whether the polishing of the wafer (W) is continued or stopped.

### EMBODIMENTS FOR CARRYING OUT THE INVENTION

Hereinafter, the present embodiments will be described in detail with reference to Examples, but the scope of the present embodiments is not limited to the Examples.

### Example 1

A polishing pad (HD-319B, SKC Solmics) was prepared by bonding a top pad (thickness: 2 mm) and a sub pad (thickness: 1.3 mm) with a hot melt adhesive. The prepared polishing pad was punched to form a hole in the top pad. Aluminum foil was fixed to the bottom of the hole to form a light reflector (thickness: 0.1 mm). Next, a composition for forming a light transmitting polymer region in the hole where the light reflector has been fixed (a composition comprising a urethane-based prepolymer (NCO %: 8% by weight) and a curing agent (4,4′-methylenebis(2-chloroaniline))) was added and cured at 110° C. to form a light transmitting polymer region, thereby preparing a polishing pad comprising a light transmitting region.

### Example 2

The polishing pad prepared in Example 1 was punched, and a window region was formed adjacent to the light transmitting region using a composition comprising a urethane-based prepolymer (NCO %: 8% by weight) and a curing agent (4,4′-methylenebis(2-chloroaniline)). In such an event, a partition wall made of polyether polyol was provided between the light transmitting region and the window region.

### Test Example 1

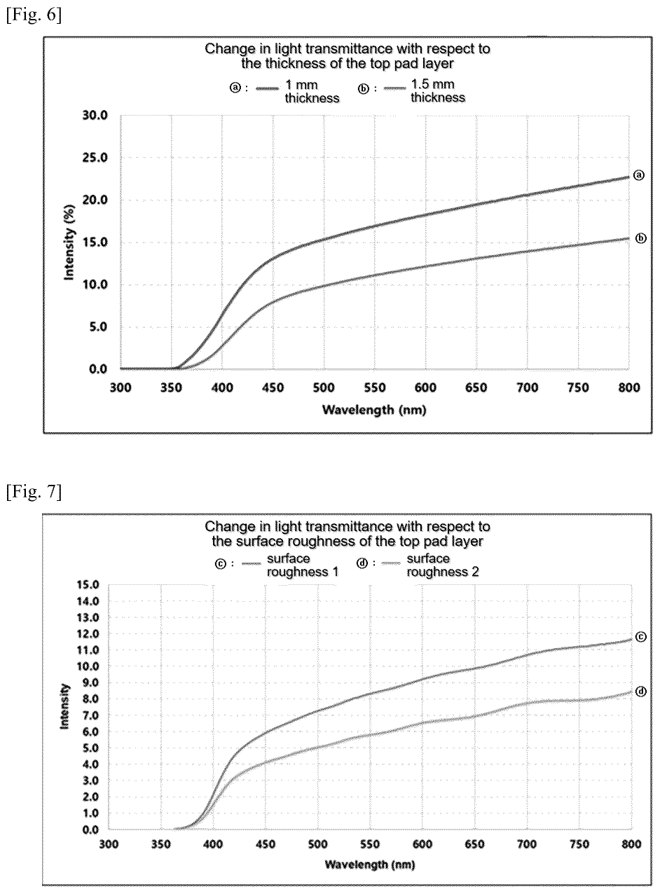

While a polishing process was carried out under the following conditions using the polishing pad of Example 1, the change in light transmittance due to the change in the thickness of the light transmitting region due to the change in the thickness of the top pad layer (polishing region) was checked using UV-2450 (SHIMADZU). The results are shown in Table 1 below and FIG. 6.
Polishing process conditions
Polishing time: 60 sec
Platen speed: 93 rpm
Head speed: 87 rpm
Wafer pressure: 3.1 psi
Slurry flow rate: 250 ml/minute

TABLE 1

| Thickness of the top pad layer | 1.5 mm | 1 mm |
|---|---|---|
| Light transmittance (at 670 nm) measured | 13.2% | 19.9% |
| through the light transmitting region | | |

Referring to Table 1 above and FIG. 6, as the polishing process was carried out using the polishing pad having a top pad layer with an initial thickness of 2 mm, the thickness of the top pad layer gradually decreased to 1.5 mm and 1 mm. Here, the thickness of the light transmitting region decreased as well. Thus, it was confirmed that the light transmittance changed whenever the thickness of the top pad layer changed when light transmittance was measured through the light transmitting region. By checking the change in light transmittance according to the change in thickness, it was possible to monitor the change in thickness of the polishing pad in real time during the polishing process.

### Test Example 2

While a polishing process was carried out under the same conditions as those of Test Example 1 using the polishing pad of Example 1, the change in light transmittance due to the change in the surface roughness of the light transmitting region due to the change in the surface roughness of the top pad layer (polishing region) was checked using UV-2450 (SHIMADZU). The results are shown in Table 2 below and FIG. 7.

TABLE 2

| | | | | Light transmittance |
|---|---|---|---|---|
| | | | | (at 450 to 500 nm) |
| | Sa | Spk | Svk | measured through the |
| Surface roughness | (μm) | (μm) | (μm) | light transmitting region |
| Surface roughness 1 | 2.2 | 2.2 | 4.1 | 6.6 |
| of the top pad layer | | | | |
| Surface roughness 2 | 1.9 | 1.8 | 3.4 | 4.6 |
| of the top pad layer | | | | |

Referring to Table 2 above and FIG. 7, as the polishing process was carried out using the polishing pad, the surface roughness of the top pad layer and that of the light transmitting region changed in conjunction. It was confirmed that the light transmittance measured through the light transmitting region when the surface roughness Sa (μm) of the top pad layer was 2.2, the surface roughness Spk (μm) was 2.2, and the surface roughness Svk (μm) was 4.1 (surface roughness 1) was different from the light transmittance measured through the light transmitting region when the surface roughness Sa (μm) of the top pad layer was 1.9, the surface roughness Spk (μm) was 1.8, and the surface roughness Svk (μm) was 3.4 (surface roughness 2). By checking the change in light transmittance according to the change in surface roughness, it was possible to monitor the change in surface roughness of the polishing pad in real time during the polishing process.

1. A polishing pad, which comprises a top pad layer, wherein the top pad layer comprises a light transmitting region for monitoring a change in the state of the polishing pad.

2. The polishing pad of claim 1, wherein the top pad layer has physical properties at the same level as those of the light transmitting region.

3. The polishing pad of claim 2, wherein the light transmitting region comprises:
a light transmitting polymer region having physical properties at the same level as those of the top pad layer; and
a light reflector provided below the light transmitting polymer region.

4. The polishing pad of claim 1, wherein a change in the thickness, or a change in the surface roughness, of the polishing pad is monitored through a change in the thickness, or a change in the surface roughness, of the light transmitting region.

5. The polishing pad of claim 1, wherein the light transmitting region has at least one surface shape selected from the group consisting of polygons, circles, rings, and spirals.

6. The polishing pad of claim 1, which further comprises a window region distinguished from the light transmitting region.

7. The polishing pad of claim 6, which further comprises a partition wall between the light transmitting region and the window region.

8. A method for monitoring a polishing process, which comprises:
(1) placing a wafer on a polishing pad comprising a top pad layer comprising a light transmitting region to carry out a polishing process;
(2) scanning light to the light transmitting region from a first optical displacement detection sensor located above the light transmitting region; and
(3) detecting light reflected from the light transmitting region by the first optical displacement detection sensor to monitor a change in the state of the polishing pad.

9. The method for monitoring a polishing process of claim 8, wherein, in step (3), a phase change, a speed change, or an intensity change of reflected light due to a change in the thickness or surface roughness of the light transmitting region is detected to monitor a change in the thickness, or a change in surface roughness, of the polishing pad.

10. The method for monitoring a polishing process of claim 8, which further comprises (4) detecting the polishing termination point of the wafer through a window region further adopted in the polishing pad.

11. The method for monitoring a polishing process of claim 10, wherein step (4) comprises:
(4-1) scanning light toward the window region from a second optical displacement detection sensor located below the window region; and
(4-2) detecting light reflected from the window region by the second optical displacement detection sensor to determine the polishing termination point of the wafer.
